(19) United States
(12) Patent Application Publication
(10) Pub. No.: US 2008/0122496 A1
(43) Pub. Date: May 29, 2008

(54) Generation of an Oscillation Signal

(75) Inventor: Christoph Wagner, Linz (AT)

Correspondence Address: BANNER & WITCOFF, LTD.;Attorneys for client 007052, 1100 13th STREET, N.W., SUITE 1200, WASHINGTON, DC, 20005-4051, US

(73) Assignee: INFINEON TECHNOLOGIES AG, Munich (DE)

(21) Appl. No.: 11/773,128

(22) Filed: Jul. 3, 2007

(30) Foreign Application Priority Data
Jul. 4, 2006 (DE) 102006030889.1-53

(51) Int. Cl. H03B 28/00

(52) U.S. Cl. 327/107

(57) ABSTRACT

Methods and apparatuses for accumulating a phase increment that comprises an overflow to a phase information signal; mapping the phase information signal to an amplitude information signal; quantizing the amplitude information signal while feeding back a quantization noise using a first filter of an n^{th} order, so that the feedback of the quantization noise comprises zeros at least two mutually different frequencies in a transfer function of the first filter; and performing digital/analog conversion of the quantized amplitude information signal to an oscillation signal.

### CROSS-REFERENCE TO RELATED APPLICATIONS

This application claims priority to German Patent Application No. 10 2006 030 889.1-53, filed on Jul. 4, 2006, incorporated by reference herein as to its entirety.

### BACKGROUND

In so-called direct digital synthesis (DDS), amplitude values of a period of an arbitrary 2π-periodic oscillation signal are stored as a lookup table (LUT) in a computer memory, for example a ROM (read only memory). As many amplitude values as possible are typically stored at as good as possible an amplitude resolution. A direct digital synthesizer (DDS) numerically calculates, in a clock cycle, a phase φ of the periodic signal using a phase accumulator, and determines associated amplitude values using the lookup table. Finally, an analog output signal is generated via a digital/analog converter (DAC) from the digital amplitude values. A tuning word forms a phase increment Δφ of the phase accumulator. That is, in a clock cycle n, phase φ[n] of the phase accumulator is increased by the phase increment Δφ, i.e. φ[n]=φ[n−1]+Δφ. A digital phase word of the accumulator has a specific number of bits, for example j-bits. Each time the phase accumulator overflows, for example in a transition from φ[n]=2^{j}−1 to φ[n+1], a complete period of the periodic signal is generated. For this reason, phase increment Δφ of the phase accumulator and a clock frequency f_{clk} of the direct digital synthesizer define an output frequency fₒᵤₜ generated by the direct digital synthesizer.

One reason a direct digital synthesizer is often used is that its output frequency fₒᵤₜ, its phase and amplitude may be altered in an accurate and rapid manner by means of digital signal processing.

In addition, one may fine-tune output frequency fₒᵤₜ and phase φ[n] and quickly switch back and forth between different output frequencies. It is these properties that have rendered DDS technology popular, among other things, for radar applications, such as in motor-vehicle radar applications.

However, such a DDS system also has several disadvantages. Mapping of phase value φ[n] to a respective amplitude value is usually accomplished by means of a lookup table, as previously described. In a conventional configuration, such a lookup table may have 100,000 bits so as to suitably accomplish mapping of a phase value φ[n] to an amplitude value of the periodic signal. Such a large lookup table typically consumes a relatively large amount of power and additionally limits the clock frequency f_{clk} of the DDS system. Also, for a high-resolution DDS system using a high-resolution lookup table, a digital/analog conversion of the amplitude value will be realized with a corresponding level of accuracy. For example, a DDS system having a 229,376 bit lookup table and a 14 bit DAC, clocked at a frequency f_{clk}=400 MHz, results in a power consumption of approximately 500 mW.

A good level of linearity and a low power consumption of a DDS system may be achieved with digital/analog converters having a low digital resolution, known as low-bit DACs. However, these low-bit DACs generate, at the output of the DDS system, a portion of interference signals which is not to be neglected, so that their immediate use will cause other problems.

### SUMMARY

Various aspects are described herein. For example, various illustrative apparatuses and methods are described. An example of a described method is as follows: accumulating a phase increment that comprises an overflow to a phase information signal; mapping the phase information signal to an amplitude information signal; quantizing the amplitude information signal while feeding back a quantization noise using a first filter of an n^{th} order, so that the feedback of the quantization noise comprises zeros at least two mutually different frequencies in a transfer function of the first filter; and performing digital/analog conversion of the quantized amplitude information signal to an oscillation signal. In addition, various illustrative apparatuses are described for performing the above method and other methods.

These and other aspects of the disclosure will be apparent upon consideration of the following detailed description of illustrative aspects.

### BRIEF DESCRIPTION OF THE DRAWINGS

A more complete understanding of the present disclosure may be acquired by referring to the following description in consideration of the accompanying drawings, in which like reference numbers indicate like features, and wherein:

FIG. 1A is a functional block diagram of an illustrative embodiment of a direct digital synthesizer;

FIG. 1B is a graph of an illustrative sequence of a phase error signal;

FIG. 2 is a functional block diagram of another illustrative embodiment of a direct digital synthesizer in accordance with various aspects described herein;

FIG. 3 is a functional block diagram of an illustrative embodiment of an amplitude quantization in accordance with various aspects described herein;

FIG. 4 is a block diagram of an illustrative embodiment of a phase quantization unit in accordance with various aspects described herein;

FIG. 5 is a graph of an output spectrum of an illustrative embodiment of a direct digital synthesizer using high order quantization noise shaping in accordance with various aspects described herein; and

FIG. 6 is a functional block diagram of an illustrative embodiment of a radar system including a direct digital synthesizer in accordance with various aspects described herein.

### DETAILED DESCRIPTION

The various aspects summarized previously may be embodied in various forms. The following description shows by way of illustration various examples in which the aspects may be practiced. It is understood that other examples may be utilized, and that structural and functional modifications may be made, without departing from the scope of the present disclosure.

Except where explicitly stated otherwise, all references herein to two or more elements being “coupled” or “connected” to each other is intended to broadly include both (a) the elements being directly connected to each other, or otherwise in direct communication with each other, without any intervening elements, as well as (b) the elements being indirectly connected to each other, or otherwise in indirect communication with each other, with one or more intervening elements. Furthermore, it should be appreciated that functional blocks or units shown in the drawings may be implemented as separate circuits in some embodiments, but may also be fully or partially implemented in a common circuit in other embodiments.

As will be discussed in more detail, in some illustrative embodiments, an apparatus is provided for generating an oscillation signal that may include a phase accumulator for accumulating a phase increment, including an overflow to a phase information signal, a phase quantizer for quantizing the phase information signal, a mapper for mapping the quantized phase information signal to an amplitude information signal, an amplitude quantizer for quantizing the amplitude information signal while feeding back the quantization noise by means of a first filter of an n^{th} order having fixed filter coefficients, so that the feedback of the quantization noise includes zeros in at least two mutually different frequencies in the transfer function, and a digital/analog converter for converting the quantized amplitude information signal to an oscillation signal.

The zeros of the frequency response of the transfer function of the feedback of the quantization noise of the amplitude quantizer may be located in a range below the clock frequency f_{clk} of the phase accumulation means, or of the digital synthesizer. The zeros may be at an output frequency fₒᵤₜ of the digital synthesizer, or in a range symmetrical around output frequency fₒᵤₜ.

In accordance with further illustrative embodiments, a digital synthesizer may include a phase accumulator with an overflow, a phase-to-amplitude mapper, and a digital/analog converter. The phase-to-amplitude mapper may be connected between the phase accumulator and the digital/analog converter. The digital synthesizer may further include a phase increment control having a fixed phase increment variation curve within a predetermined phase increment variation interval, the control's output being coupled to a phase increment default input of the phase accumulator, and a quantizer connected between the phase-to-amplitude mapper and the digital/analog converter and including a noise shaping feedback loop into which a filter of an n^{th} order having fixed filter coefficients is connected, so that the noise shaping feedback loop includes zeros at least two mutually different frequencies in the transfer function.

The zeros of the frequency response of the noise shaping feedback loop of the quantizer may be in a range below the clock frequency f_{clk} of the digital synthesizer. The zeros may be at an output frequency fₒᵤₜ of the digital synthesizer, or in a range around output frequency fₒᵤₜ. In other words, the zeros may be located, for example, at different frequencies between f=0 and f=f_{clk}, and in particular near the output frequency fₒᵤₜ, such as within the frequency range from ½fₒᵤₜ to 3/2fₒᵤₜ.

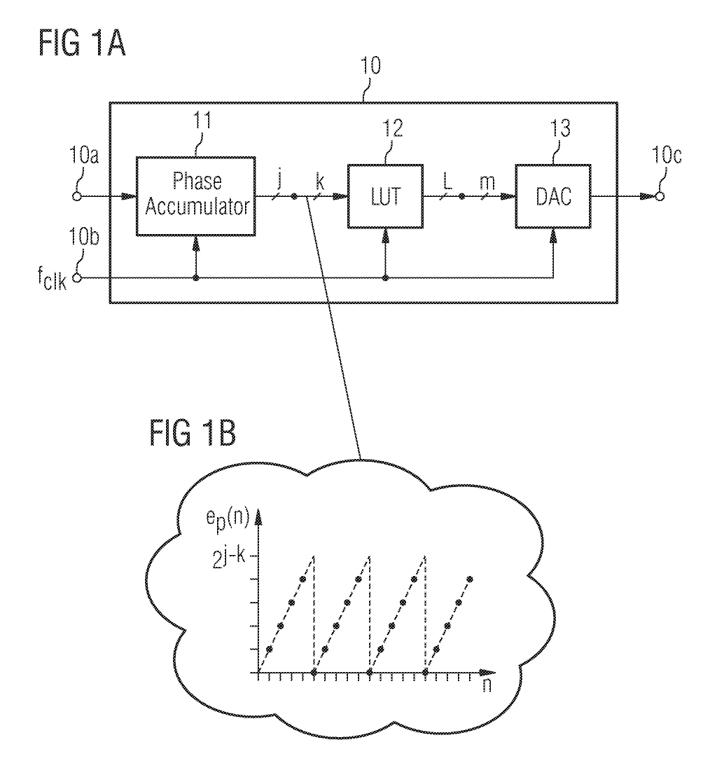

FIG. 1A depicts a functional block diagram of an illustrative embodiment of a direct digital synthesizer 10 including a phase accumulator 11, a lookup table 12, and a digital/analog converter 13. An input 10a of direct digital synthesizer 10 is coupled to phase accumulator 11. At its output, phase accumulator 11 is coupled to lookup table 12, which, in turn, is coupled, at its output, to DAC 13. At one output 10c of the DDS, DAC 13 provides an analog oscillation signal. A second input 10b of DDS 10 is coupled to phase accumulator 11, to lookup table 12 and to DAC 13 for clock recovery.

Phase accumulator 11 may include a j-bit phase register (not shown), which stores a digital phase increment Δφ present at an input 10a, and adds this phase increment Δφ to a phase register content φ[n] via a j-bit adder. The digital phase increment Δφ is input into the phase register by, for example, a phase increment control. At each clock n, this digital phase increment Δφ is added to the content φ[n] of the phase register. A clock signal having a clock frequency f_{clk} is present at the input 10b of DDS 10. The phase increment Δφ represents a phase angle increment which is added to the preceding phase value every 1/f_{clk} seconds so as to generate a linearly increasing digital phase value φ[n]. The phase value is generated by means of the 2^{j} overflow property of the j-bit phase accumulator 11. The rate of overflows corresponds to output frequency fₒᵤₜ in accordance with:

$${f}_{out} = \frac{Δ ϕ \cdot {f}_{clk}}{{2}^{j}} ∀ {f}_{out} \leq {f}_{clk} / 2. \qquad ( 1 )$$

Formula (I) stems from the sampling theorem according to Shannon. Phase increment Δφ is an integral number, which is why a frequency resolution Δf of DDS 10 results, with Δφ=1, in which:

$$Δ f = \frac{{f}_{clk}}{{2}^{j}} . \qquad ( 2 )$$

Lookup table 12 maps the digital phase information signal φ[n] to amplitude values r[n] of a sinusoidal oscillation. In an ideal case, i.e. with no phase and amplitude quantization, what results is an output sequence of lookup table 12:

$$r [ n ] - sin ( 2 π \frac{ϕ [ n ]}{{2}^{j}} ) , \qquad ( 3 )$$

wherein φ[n] represents the j-bit phase register value of the n^{th} clock period.

The output of lookup table 12 is fed to digital/analog converter 13, which gives rise to an analog oscillation signal. It can be shown that the output spectrum of DDS 10 includes frequencies f=n·f_{clk}±fₒᵤₜ (n=0, 1, . . . ). The amplitudes of these frequency components are weighted with a function:

$$sinc ( \frac{f}{{f}_{clk}} ) . \qquad ( 4 )$$

This effect may be responded to, for example, with an inverse sinc(f/f_{clk}) filter in accordance with DAC 13.

Noise and further interference-signal portions may arise, for example, by cutting off the j-bit phase accumulator output signal φ[n] in that only k most significant bits of the j-bit phase information signal φ[n] are utilized for addressing the amplitude values of lookup table 12. If only the m most significant bits are taken into account by a one-bit amplitude output signal of lookup table 12 for the digital/analog conversion, the same may apply. Also, distortions may arise due to a compression of the amplitude values of lookup table 12 and to the finite accuracy of the amplitude values stored within lookup table 12.

In an ideal case, i.e. without phase and amplitude information being cut off and/or quantized, the output sequence r[n] of DDS 10 is given by:

$$r [ n ] = sin ( 2 π \frac{Δ ϕ}{{2}^{j}} n ) , \qquad ( 5 )$$

wherein n designates the n^{th} clock period.

The memory space that would be used for encoding the complete word width (j bits) of phase accumulator 11 within lookup table 12 may be typically too large to be economical. Therefore, for example, only the k most significant bits of the phase accumulator output signal may be used for addressing lookup table 12 so as to determine the amplitude values of the periodic oscillation signal. If the output of phase accumulator 11 is limited, or quantized, to the k most significant bits before the lookup operation is performed, the output sequence of DDS 10 would change to:

$$r [ n ] = sin ( \frac{2 π}{{2}^{k}} \frac{Δ ϕ}{{2}^{j - k}} n ) . \qquad ( 6 )$$

Equation (6) may be rewritten to read:

$$r [ n ] = sin ( \frac{2 π}{{2}^{j}} ( Δ ϕ \cdot n - {e}_{ϕ} [ n ] ) ) , \qquad ( 7 )$$

wherein e_{φ}[n] signifies a phase error signal that may arise as a result of the quantization of the j-bit phase information signal to k most significant bits. Phase error signal e_{φ}[n] may be limited, in terms of its magnitude, in accordance with e_{φ}[n]<2^{j-k}, and also may be periodic. An example of a sequence of the phase error signal e_{φ}[n] is shown in FIG. 1B.

As may be seen from FIG. 1B, phase error signal e_{φ}[n] may be periodic due to the overflow functionality of phase accumulator 11, and thus may form the basis of the periodic properties of direct digital synthesizer 10.

Quantizing the digital amplitude signal r[n] at the output of lookup table 12 from 1 to m most significant bits may also lead to an interference in the output spectrum of direct digital synthesizer 10. If one assumes that the phase quantization error e_{φ}[n] does not exist, the input signal to digital/analog converter 13 is given:

$$sin ( \frac{2 π}{{2}^{j}} Δϕ \cdot n ) - {e}_{A} [ n ] , \qquad ( 8 )$$

wherein e_{A}[n] represents the amplitude quantization error caused by a lookup-table amplitude word of a finite length. The sequence of the amplitude quantization error e_{A}[n] also may be periodic.

To cancel the periodicity of the quantization errors of the phase information signal and of the amplitude information signal, and thus to spread the interference energy of the quantization noise into a broad-band noise, a principle of quantization error feedback may be applied. Quantization error feedback may result in noise shaping. Noise shaping is understood to mean methods of shaping the spectrum of undesired interference and/or noise signals in a controlled manner. In principle, by means of noise shaping, interference power may be transformed, from certain specific spectral ranges, to frequency ranges located outside a useful-signal band. In this context, the transformation may be conducted such that the spectral components shifted within the frequency range will have less influence on the useful signal, i.e. the interference power in the useful-signal band may be reduced. What this may mean, in concrete terms, for the application of noise-shaping methods within the DDS, is that interference-signal components located near the synthesized frequency fₒᵤₜ may be shifted to more remote ranges.

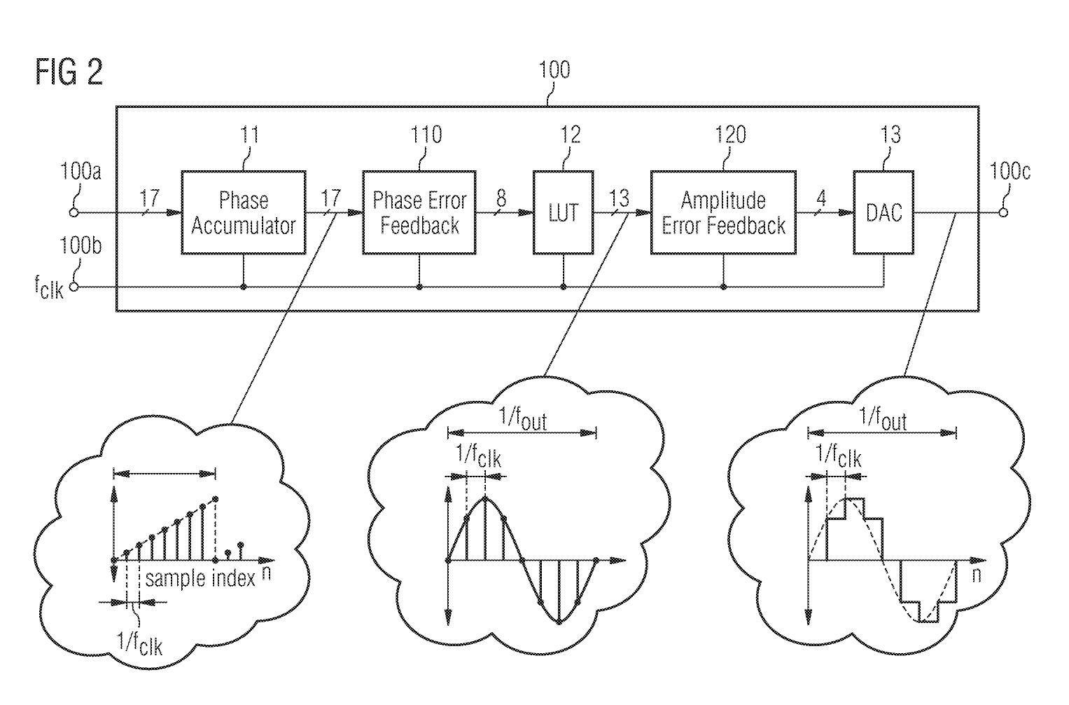

FIG. 2 shows a functional block diagram of an illustrative embodiment of a direct digital synthesizer, wherein the principle of quantization error feedback is applied.

FIG. 2 shows an illustrative direct digital synthesizer 100 having inputs 100a and 100b, and an output 100c. DDS 100 has a phase accumulator 11 wired, at its output, to a phase quantizer 110. The output of phase quantizer 110, in turn, is coupled to a mapper 12 in the form of a lookup table that maps a phase information signal to an amplitude information signal. The amplitude information signal present at the output of mapper 12 is forwarded to a digital/analog converter 13 via an amplitude quantizer 120. The output of the digital/analog converter is coupled to output 100c of direct digital synthesizer 100. Also, input 100b of DDS 100 is coupled, for clock supply purposes, to all of the previously described blocks of DDS 100.

In the direct digital synthesizer 100 shown in FIG. 2, phase quantizer 110, including a phase quantization error feedback structure, is connected between the output of phase accumulator 11 and the input of ROM lookup table 12. Amplitude quantizer 120, including an amplitude quantization error feedback structure, is connected between the output of lookup table 12 and DAC 13. In this context, with quantization error feedback structures 110 and 120, respectively, feedback filters with fixed filter coefficients may be used.

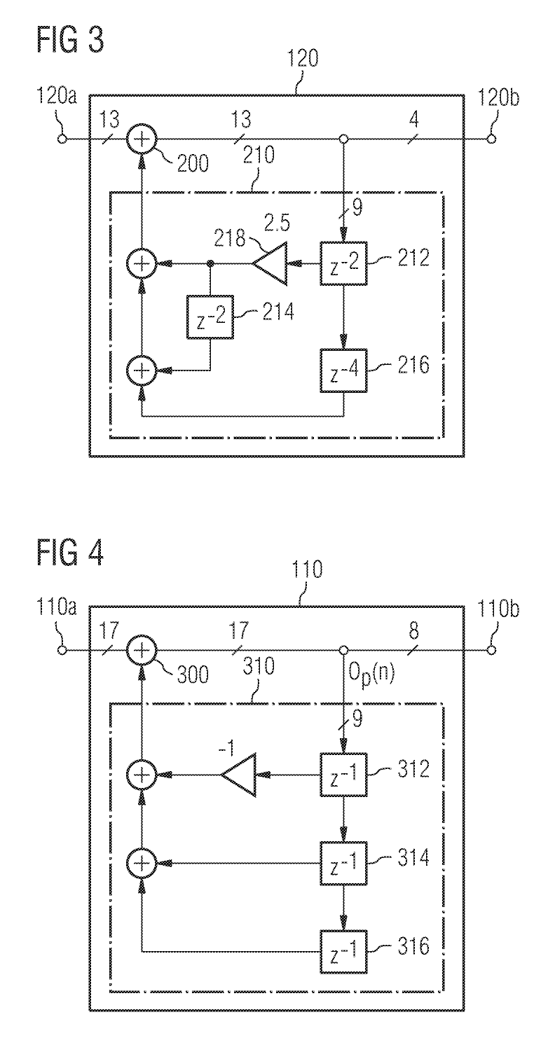

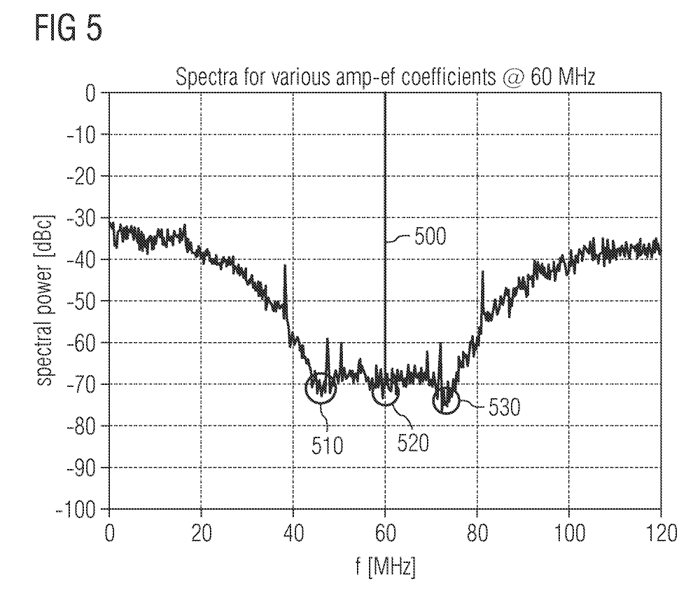

Phase accumulator 11 may have, for example, a 17 bit wide phase increment Δφ, i.e. j=17, supplied to it via input 100a of direct digital synthesizer 100. However, a tuning word of a smaller width may alternatively be used. In the present example, phase accumulator 11 may work with a word width of 17 bits, which enables a high clock frequency f_{clk} of the DDS system. The 17 bit phase accumulator output signal is quantized to an eight bit input signal (k=8) for lookup table 12 by means of phase quantizer 110 that includes a phase quantization error feedback structure as will be described in more detail below with reference to FIG. 4. Due to simple lookup-table compression techniques, lookup table 12 may include, for example, only 512 bits, which may enable low power consumption and high-speed implementation of DDS 100. For example, a π/4 compression and sine phase difference encoding technique may be employed. The output of lookup table 12 may include an amplitude information signal having a word width of, e.g., 13 bits, i.e. 1=13. The 13 bit amplitude information signal may be quantized to a four bit input signal (m=4) for DAC 13 by means of amplitude quantizer 120 that includes an amplitude quantization error feedback structure that will be described in more detail below with reference to FIG. 3.

FIG. 3 shows an illustrative embodiment of amplitude quantizer 120 for quantizing the amplitude information signal while shaping the quantization noise by means of a first sixth-order filter with fixed filter coefficients.

Amplitude quantizer 120 as shown includes a phase information signal input 120a and an amplitude information signal output 120b. An adder, such as a one-bit adder 200, adds a one bit amplitude information signal to an output signal of a first FIR filter 210 (FIR=finite impulse response) switched into a feedback loop. Adder 200 is coupled to input 120a. The m most significant bits of the one-bit output of adder 200 are fed to output 120b of amplitude quantizer 120, whereas the (1−m) least significant bits of the one-bit amplitude information signal are fed, at the output of adder 200, to the input of FIR filter 210 of the feedback loop.

In some embodiments, FIR filter 210 includes, for returning the amplitude quantization error e_{A}[n], two two-fold delay members 212, 214 and a four-fold delay member 216. The term “n-fold delay member” is intended to designate a device that outputs an incoming digital value in such a manner that same is delayed by n clocks. First two-fold delay member 212 has first and second outputs. The first output is coupled to an input of a multiplier 218, whereas the second output is coupled to an input of four-fold delay member 216. One output of multiplier 218 is connected to an input of second two-fold delay member 214.

The output signal of FIR filter 210 is configured such that an output signal of the first output of the first two-fold delay member 212 is multiplied, by multiplier 218, for example by a factor of 2.5, and in that the output signal of multiplier 218, which corresponds to the result of the multiplication, is in turn delayed by the second two-fold delay member 214. In addition, an output signal of the second output of the first two-fold delay member 212 is delayed by the four-fold delay member 216. To form the output signal of FIR filter 210, the output signal of multiplier 218, the output signal of the second two-fold delay member 214, and the output signal of the four-fold delay member 216 are added. This may mean that the transfer function of FIR filter 210 in the feedback path for feeding back the quantization error e_{A}[n] of the amplitude information signal includes a z transform of the pulse response of filter 210, in accordance with:

F₁(z)=2.5z⁻²+2.5z⁻⁴+z⁻⁶. (9)

The transfer function of amplitude quantizer 120 with regard to the amplitude quantization noise e_{A}[n] represented in the z domain may thus result in, in accordance with the present illustrative embodiment:

H_{A}(z)=1−F₁(z)=1−2.5z⁻²−2.5z⁻⁴−z⁻⁶. (10)

In some embodiments, the coefficients of filter F₁(z) 210, or the coefficients of transfer function H_{A}(z), may be selected such that the zeros of the frequency response of transfer function H_{A}(z) of amplitude quantization means 120 are in a range below clock frequency f_{clk} of the phase accumulation means and/or of the digital synthesizer, i.e. in a range 0<f<f_{clk}. In this context, the zeros may occur at different frequencies. In particular, the filter coefficients of filter F₁(z) 210 may be selected, in some embodiments, such that the frequency zeros of H_{A}(z) are at an output frequency fₒᵤₜ of the digital synthesizer, and/or in a symmetrical range around output frequency fₒᵤₜ.

A frequency response of the transfer function H_{A}(z) of amplitude quantization means 120 may be determined, with regard to the amplitude quantization noise e_{A}[n], by means of the context:

$${z}^{- 1} = {e}^{- j ω {T}_{clk}} = {e}^{- j 2 π \frac{f}{{f}_{clk}}} , \qquad ( 11 )$$

wherein ω stands for an angular frequency 2πf, and T_{clk} stands for a clock duration of 1/f_{clk}.

For forming the quantization noise e_{A}[n] of the amplitude signal, filter 210 need not necessarily exhibit any zeros at the frequency of f=0 in the feedback loop. A zero at the frequency of f=f_{clk}/4 signifies a filter coefficient of zero, so that the filter structure of the FIR filter 210 of amplitude quantization means 120 may be highly simplified. The transfer function of amplitude quantizer 120 with regard to the amplitude quantization noise H_{A}(z)=1−F₁(z) of the sixth order may be composed of three sections of the second order, respectively, in the form of, for example, H_{A}(z)=(1+a·z⁻¹+z⁻¹)·(1+b·z⁻¹+z⁻)·(1+c·z⁻¹+z⁻²). This may allow the design to be simplified, since in this case only one filter coefficient, respectively, is adjustable, and the others automatically provide a realizable and stable filter. If, for example, a=0, a zero of the transfer function H_{A}(z) would result at f₁=f_{clk}/4. This may be explained by the fact that a filter having a transfer function (1+a·z⁻¹+z⁻²) exhibits a zero at f=arccos(−a/2)·f_{clk}/(2π), and thus the following results: a=0 f₁=f_{clk}/4.

When in the equation H_{A}(z)=(1+a·z⁻¹+z⁻²)·(1+b·z⁻¹+z⁻²)·(1+c·z⁻¹+z⁻²), i.e. a=0, and the coefficients b and c are set to have the same magnitude with different signs, specifically are set to the value of b=−c=−√2/2=−0.707, the transfer function set forth in equation (10) will result from multiplying. The filter coefficient of 2.5 may be realized in hardware by means of, for example, shifting and adding operations. The zeros of H_{A}(z) resulting from b and c occur at the frequencies f₂=arccos(−b/2)·f_{clk}/(2π)=arccos(0.707/2)·f_{clk}/(2π) and f₃=arccos(−c/2)·f_{clk}/(2π)=arccos(−0.707/2)·f_{clk}/(2π). With a clock frequency of, for example, f_{clk}=240 MHz, the feedback loop of amplitude quantizer 120 would have zeros at the frequencies f₂≈46 MHz, f₁≈60 MHz=fₒᵤₜ=f_{clk}/4 and f₃≈74 MHz. The zeros at f₂ and f₃ thus may be located symmetrically around the zero at f₁=fₒᵤₜ=f_{clk}/4.

The symmetry of the frequency zeros of H_{A}(z) around output frequency fₒᵤₜ, in particular fₒᵤₜ=f_{clk}/4, may allow the filter function F₁(z) for be simplified for amplitude quantization, since every other filter coefficient would disappear. In this manner, circuit expenditure may be reduced, for example, by savings in terms of adders.

Filter 210 shown in FIG. 3 is a sixth-order filter. In terms of complexity for a hardware implementation, however, this would not necessarily impose any more expense (or very little more) than would implementing a third-order filter.

It is be noted that other FIR filter structures also may be feasible in the feedback path for feeding back the quantization error e_{A}[n] of the amplitude information signal. One may generally represent, for example, a z transform of the impulse response of a sixth-order FIR filter in accordance with:

F₁(z)=a₀+a₁z⁻¹+a₂+z⁻²a₃z⁻³+a₄z⁻⁴+a₅z⁻⁵+a₆z⁻⁶ (12)

wherein a₀, a₁, a₂, a₃, a₄, a₅, a₆ stand for the specified filter coefficients. The choice of the filter coefficients may depend, for example, on the clock frequency f_{clk} of the DDS, and/or on the desired spectral properties of the output signal.

FIG. 4 shows an illustrative embodiment of phase quantizer 110 for quantizing the phase information signal while shaping the quantization noise e_{φx[n] by means of a third-order filter with fixed filter coefficients.}

FIG. 4 shows phase quantizer 110 having a phase information signal input 110a and a phase information signal output 110b. An adder 300, which adds a j-bit phase information signal to an output signal of an FIR filter 310 switched into a feedback loop, is coupled to input 110a. The k most significant bits of the j-bits wide output of adder 300 are fed to output 110b of phase quantization means 110, whereas the (j−k) least significant bits of the j-bits wide phase information signal are fed, at the output of adder 300, to the input of FIR filter 310 of the feedback loop.

FIR filter 310 for returning the phase quantization error e_{φ}[n] has three delay members 312, 314, 316 connected in succession. First delay member 312 has first and second outputs. The first output is coupled to an input of a multiplier 318, whereas the second output is coupled to an input of second delay member 314. Second delay member 314 also has first and second outputs, one output being connected to an input of third delay member 316.

The output signal of FIR filter 310 is formed in that an output signal of the first output of first delay member 312 is multiplied, by multiplier 318, for example by a factor of −1, and in that the output signal of multiplier 318 is added to the sum of the outputs of the two subsequent delay members 314 and 316. This may mean that the transfer function of FIR filter 310 in the feedback path for feeding back the quantization error e_{φ}[n] of the phase information signal has a z trans-form of the pulse response of the filter in accordance with:

F₂(z)=−z⁻¹+z⁻²+z⁻³. (13)

The transfer function of quantizer 110 with regard to the phase quantization noise e_{φ}[n], represented in the z domain, thus results in:

H_{φ}(z)=1−F₂(z)=1+z⁻¹−z⁻²−z⁻³. (14)

Phase quantizer 110 may be implemented, for example, using only adders and/or subtractors, and registers, all of which are readily available using a variety of technologies. As was already described previously, H_{φ}(z), too, may be composed of a second-order portion (zero within the frequency band) and a first-order portion (zero at the edge of the frequency band at f=0). Phase quantizer 110 may exhibit a zero in the transfer function H_{φ}(z) of phase quantization means 110 with regard to phase quantization noise e_{φ}[n], since the phase information is in a range of [0,2π] in a binary representation. The zero of H_{φ}(z) at f=0 may be desirable, since the output signal of phase accumulator 11 may be only positive and thus have a steady component which, however, may not be changed by filter 310. This is why, in accordance with the invention, a third-order FIR filter may be employed.

It should be noted that other FIR filter structures may be feasible in the feedback path for feeding back the quantization error e_{φ}[n] of the phase information signal. Generally, a z transform of the pulse response of a third-order FIR filter may be represented in accordance with:

F₁(z)=b₀+b₁z⁻¹+b₂z⁻²+b₃z⁻³ (15)

wherein b₀, b₁, b₂, b₃ stand for the fixed filter coefficients. The filter coefficients may be chosen to depend, for example, on the clock frequency f_{clk} of the DDS, and/or on the desired spectral properties of the output signal.

A quantization error feedback may cancel a periodicity of the quantization errors e_{φ}[n] and/or e_{A}[n], and may thus convert interference energy concentrated in spectral terms to broad-band noise. Quantization noise of phase and amplitude may be formed by the respective quantization error feedback structures 110 and 120. In accordance with some embodiments, quantization noise shaping may be performed by means of feedback filters 210 and 310, respectively, with fixed filter coefficients, in such a manner that a relatively large part of the output spectrum of direct digital synthesizer 100 may exhibit a reduced quantization noise power, and such that the entire quantization noise power may be concentrated near DC (direct current) and a frequency of f=f_{clk}/2. In accordance with some embodiments, a frequency range of approx. 0.3·f_{clk}/2 may remain as a usable frequency range, for example for FMCW radar applications without necessarily needing to specifically adapt the filter coefficients of the quantization error feedback filters to the output frequency fₒᵤₜ of direct digital synthesizer 100.

At a suitable clock frequency f_{clk}, the usable spectral range adjusted by the fixed filter coefficients and, thus, by the zeros of the transfer function of the noise feedback, may be sufficiently large and may even be adapted to utilize direct digital synthesizer 100, as a reference and/or modulation source, for example for a PLL (phase locked loop) of a motor-vehicle radar system. In accordance with some embodiments, the structure of direct digital synthesizer 100 may be optimized for generating so-called frequency sweeps as are often used, for example, in FMCW radar systems.

Lookup table 12, depicted in FIG. 2, for mapping the phase information signal φ[n] to the amplitude information signal, provides a one-bit (1>k) amplitude-value output word. This may reduce or even eliminate all interference-signal components that stem from the quantization of the phase information signal φ[n] within the signal bandwidth of direct digital synthesizer 100.

FIG. 5 shows an output spectrum of an illustrative embodiment of a direct digital synthesizer using a phase quantizer for quantizing the phase information signal in accordance with FIG. 4 and an amplitude quantizer for quantizing the amplitude information signal in accordance with FIG. 3. FIG. 5 shows the illustrative output spectrum plotted over a frequency f.

Next to an output signal 500 of a direct digital synthesizer having an output frequency of, e.g., fₒᵤₜ=60 MHz at a clock frequency of, e.g., f_{clk}=240 MHz, the zeros of the transfer function H_{A}(z) of amplitude feedback structure 120 depicted in FIG. 3 may clearly be seen. As shown, a first zero 510 is at least approximately at a frequency f₁=46 MHz. A second zero 520 is at least approximately at the output frequency fₒᵤₜ=60 MHz. Finally, a third zero 530 of amplitude noise feedback loop 120 is at least approximately at a frequency f₃=74 MHz.

The performance of quantization error feedback structure 120 in this example becomes clear in terms of a low noise level in the region between f₁≈46 MHz and f₃≈74 MHz. In this region, a spectral noise power density is at approx. −115 dBc/Hz. It is only the interference-signal components within this frequency band of f₁≈46 MHz to f₃≈74 MHz that may negatively affect a system performance of direct digital synthesizer 100, since all other frequencies outside this frequency band may be filtered out by means of a bandpass filter, not shown in FIGS. 1A-4, so as to reduce an overall noise power in the DDS output signal. In direct digital synthesizer 100, interference-signal components of the carrier signal may be suppressed, since in-band interference signals may stem from the phase signal quantization, which may automatically adjust to output frequency fₒᵤₜ of direct digital synthesizer 100.

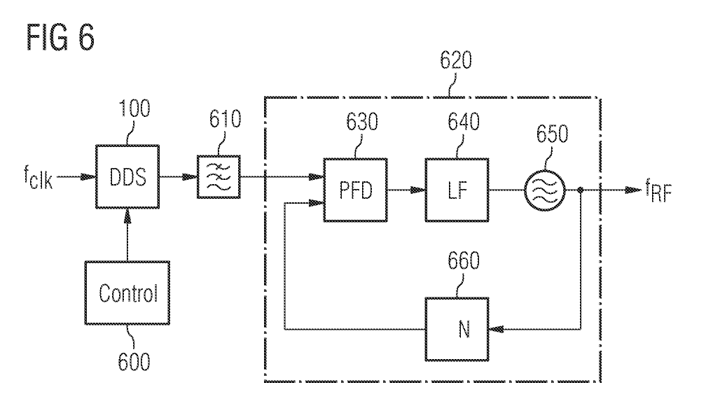

As was already described above, such an apparatus may be employed, for example, in motor-vehicle radar systems, such as in FMCW radar systems. A schematic block diagram of an illustrative circuit for frequency generation in such a radar system is depicted in FIG. 6.

As shown in FIG. 6, direct digital synthesizer 100 obtains, at its input, a clock signal having a frequency f_{clk}. A phase increment Δφ is provided via a controller 600. At its output, direct digital synthesizer 100 is coupled to a low-pass filter 610, which, in turn, provides, at its output, a reference signal for a PLL 620 (PLL=phase locked loop). At its input, PLL 620 has a phase frequency detector 630 coupled, on the output side, to a low-pass filter 640. The output signal of the low-pass filter controls a VCO 650 (VCO=voltage controlled oscillator), whose oscillation signal is fed back to a second input of phase frequency detector 630 via a frequency divider 660.

Output frequency f_{RF} may be higher, by a factor of N, than the frequency fₒᵤₜ generated by direct digital synthesizer 100. The reference frequency fₒᵤₜ generated by the DDS 100 for the PLL 620 may range from, for example, 100 MHz to 1 GHz. Phase frequency detectors may operate within a frequency range of, for example, several hundred KHz up to several hundred MHz.

In FMCW radar systems, frequency sweeps are typically performed. This frequency sweep may be created, for example, in that the carrier frequency f_{RF} of the radar system is increased, within a specific time interval T, from a starting value to a final value. This increase may be linear, for example. A modulation of radar output frequency f_{RF} may be achieved with the system depicted in FIG. 6 in that the controller 600 increases, within time interval T, phase increment Δφ from a starting value to a final value. This may mean that the reference frequency fₒᵤₜ that prevails at the output of low-pass filter 610, for PLL 620, and thus also the radar output frequency f_{RF} generated by the PLL, is modulated from a starting value to a final value within time interval T.

As was already shown in FIG. 5, one may generate an output spectrum having a very low noise level, for example in a frequency band of approx. 25 MHz, using a direct digital synthesizer with quantization error feedback structures both for phase information signals and for amplitude information signals, by means of noise shaping. In this frequency band around an output frequency fₒᵤₜ of the output signal generated of the direct digital synthesizer, the output frequency fₒᵤₜ of the DDS may be modulated without necessarily having any negative influence on the noise level generated. The spectral shape of the noise may depend only on the fixed filter coefficients of the quantization noise feedback means both for amplitude information signals and for phase information signals, and on the clock frequency f_{clk} of the DDS. Thus, the output frequency fₒᵤₜ, generated by a DDS, for a PLL may be varied, as is depicted for example in FIG. 6, within a frequency range defined by the filter coefficients and the clock frequency f_{clk} of the DDS, without necessarily increasing the noise power within this frequency range. This may be desirable, in turn, for generating a frequency sweep, as is used, for example, in radar applications such as FMCW radar applications.

It is also noted that in various embodiments, word widths may be used that differ from the above-described word widths for the phase information signal, the phase quantization noise, the amplitude information signal, and the amplitude quantization noise. A choice of these word widths may depend, among other things, on the performance of the hardware used.

In various embodiments, the phase quantizer and/or the amplitude quantizer may each be implemented as higher-order multiple error feedback structures for quantizing the phase information signal and the amplitude information signal, respectively, and may be optimized for a hardware and/or software implementation.

Due to the quantization of the phase information signal, a relatively small lookup table may be used for mapping the phase information signal to the amplitude information signal. Moreover, due to the quantization of the amplitude information signal, low-bit DACs may be employed, and it may be desirable, due to the multiple quantization error feedback structures used, to spectrally shape the quantization noise such that it has a particularly low spectral power density in a range around output frequency fₒᵤₜ of the DDS.

Thus, various embodiments as described herein may enable a more performance-efficient DDS system using smaller interference-signal components that may be particularly suited to the low spectral power density of the quantization noise in a range around output frequency fₒᵤₜ of the DDS system, for applications such as LFMCW radar systems (LFMCW=linear frequency modulated continuous wave).

In addition, the features described herein are not limited to radar applications, but may also be employed in other applications, such as in function generators that generate various signal shapes. In addition, various embodiments may be suitable for generating fast and accurate frequency and phase changes, for example for modulation purposes.

Any of the various functions described herein may also be implemented in software. The implementation may be effected by storing computer-readable instructions and/or data on a computer-readable storage medium, such as a magnetic and/or optical disk, magnetic tape, and/or memory. These computer-executable instructions may be read and executed by a programmable computer.

1. An apparatus, comprising:
a phase accumulator configured to accumulate a phase increment comprising an overflow to a phase information signal;
a phase quantizer configured to quantize the phase information signal;
a mapper configured to map the quantized phase information signal to an amplitude information signal;
an amplitude quantizer having a first filter of an n^{th} order having fixed filter coefficients and defining a transfer function, the amplitude quantizer configured to quantize the amplitude information signal and to feed back quantization noise using the first filter, wherein the feedback of the quantization noise comprises zeros at least two mutually different frequencies in the transfer function; and
a digital/analog converter configured to convert the quantized amplitude information signal to an oscillation signal.

2. The apparatus of claim 1, wherein n=6, and a z transform of a pulse response of the first filter is:
F₁(z)=a₂z⁻²+a₄z⁻⁴+a₆z⁻⁶,
wherein a₂, a₄ and a₆ are each a filter coefficient.

3. The apparatus of claim 1, wherein n=6, and a z transform of a pulse response of the first filter is:
F₁(z)=2.5z⁻²+2.5z⁻⁴+z⁻⁶.

4. The apparatus of claim 1, wherein the amplitude quantizer is configured to quantize the amplitude information signal from first words each having a width of one bit to second words each having a width of m bits, wherein m<1.

5. The apparatus of claim 4, wherein the amplitude quantizer is configured to generate the second words from the m most significant bits of the first words, and the first filter is configured to filter the remaining (1−m) least significant bits of the first words.

6. The apparatus of claim 1, wherein the phase quantizer further comprises a second filter of a third order having fixed filter coefficients and exactly one zero in a z transform of a pulse response of the second filter, and wherein the z transform of the pulse response of the second filter is:
F₂(z)=b₁z⁻¹+b₂z⁻²+b₃z⁻³,
wherein b₁, b₂, b₃ are each a filter coefficient.

7. The apparatus of claim 6, wherein the z transform of the pulse response of the second filter is:
F₂(z)=−z⁻¹+z⁻²+z⁻³.

8. The apparatus of claim 1, wherein the amplitude quantizer is configured to quantize the amplitude information signal from first words each having a width of j bits to second words each having a width of k bits, wherein k<j.

9. The apparatus of claim 8, wherein the amplitude quantizer is configured to generate the second words from the m most significant bits of the first words, and the first filter is configured to filter the remaining (j−k) least significant bits of the first words.

10. An apparatus, comprising:
phase accumulation means for accumulating a phase increment comprising an overflow to a phase information signal;
phase quantization means for quantizing the phase information signal;
mapping means for mapping the quantized phase information signal to an amplitude information signal;
amplitude quantization means having a first filter of an n^{th} order having fixed filter coefficients and defining a transfer function, the amplitude quantization means for quantizing the amplitude information signal and for feeding back quantization noise using the first filter, wherein the feedback of the quantization noise comprises zeros at least two mutually different frequencies in the transfer function; and
digital/analog conversion means for converting the quantized amplitude information signal to an oscillation signal.

11. An apparatus, comprising
a phase accumulator comprising an overflow having a phase increment default input and a j-bit phase information signal output;
an adder comprising a first j-bit adder input coupled to the j-bit phase information signal output, a second adder input, and a j-bit adder output;
a phase noise shaping feedback loop coupled between the (j−k)^{th} least significant bits of the j-bit adder output and the second adder input;
a first filter having fixed coefficients configured to be switched into the phase noise shaping feedback loop;
a lookup-table memory comprising a k-bit phase information signal input and a one-bit amplitude information signal output;
a one-bit adder comprising a first one-bit adder input coupled to the one-bit amplitude information signal output, a second adder input and a one-bit adder output;
an amplitude noise shaping feedback loop coupled between the (1−m)^{th} least significant bits of the one-bit adder output and the second adder input;
a second filter comprising fixed filter coefficients configured to be switched into the amplitude noise shaping feedback loop, so that the amplitude noise shaping feedback loop comprises zeros at least two mutually different frequencies in a transfer function of the second filter; and
a digital/analog converter comprising an m-bit amplitude information signal input.

12. The digital synthesizer of claim 11, wherein the second filter comprises a sixth order filter, and a z transform of a pulse response of the second filter is:
F₁(z)=a₂z⁻²a₄z⁻⁴+a₆z⁻⁶.
wherein a₂, a₄ and a₆ are each a filter coefficient.

13. The digital synthesizer of claim 11, wherein the second filter comprises a sixth order filter, and a z transform of a pulse response of the second filter is:
F₁(z)=2.5z⁻²+2.5z⁻⁴+z⁻⁶.

14. The digital synthesizer of claim 11, wherein the first filter comprises a third order filter, and a z transform of a pulse response of the first filter is:
F₂(z)=b₁z⁻¹+b₂z⁻²+b₃z⁻³,
wherein b₁, b₂ and b₃ are each a filter coefficient.

15. The digital synthesizer of claim 11, wherein the first filter comprises a third order filter, and a z transform of a pulse response of the first filter is:
F₁(z)=−z⁻¹+z⁻²+z⁻³.

16. An apparatus, comprising
a phase accumulator comprising an overflow and a phase increment default input;
a digital/analog converter;
a phase-to-amplitude mapper coupled between the phase accumulator and the digital/analog converter;
a phase increment control having an output and defining a fixed phase increment variation curve within a predetermined phase increment variation interval, the output of the phase increment control being coupled to the phase increment default input; and
a quantizer coupled between the phase-to-amplitude mapper and the digital/analog converter and comprising a noise shaping feedback loop that comprises an n-order filter having fixed filter coefficients and configured to be switched into the noise shaping feedback loop so that the noise shaping feedback loop comprises zeros at least two mutually different frequencies in a transfer function of the filter.

17. The digital synthesizer of claim 16, wherein the filter comprises a sixth order filter, and a z transform of a pulse response of the filter is:
F₁(z)=a₂z⁻²a₄z⁻⁴+a₆z⁻⁶,
wherein a₂, a₄ and a₆ are each a filter coefficient.

18. The digital synthesizer of claim 16, wherein the filter comprises a sixth order filter, and a z transform of a pulse response of the filter is:
F₁(z)=2.5z⁻²+2.5z⁻⁴+z⁻⁶.

19. A method, comprising:
accumulating a phase increment that comprises an overflow to a phase information signal;
mapping the phase information signal to an amplitude information signal;
quantizing the amplitude information signal while feeding back a quantization noise using a first filter of an n^{th} order, so that the feedback of the quantization noise comprises zeros at least two mutually different frequencies in a transfer function of the first filter; and
performing digital/analog conversion of the quantized amplitude information signal to an oscillation signal.

20. The method of claim 19, wherein quantizing the amplitude information signal is performed such that the first filter comprises a sixth order filter, and a z trans-form of a pulse response of the first filter is:
F₁(z)=a₂z⁻²+a₄z⁻⁴+a₆z⁻⁶,
wherein a₂, a₄ and a₆ are each a filter coefficient.

21. The method of claim 19, wherein quantizing the amplitude information signal is performed such that the first filter comprises a sixth order filter, and a z trans-form of a pulse response of the first filter is:
F₁(z)=2.5z⁻²+2.5z⁻⁴+z⁻⁶.

22. The method of claim 19, wherein quantizing the amplitude information signal comprises quantizing the amplitude information signals from first words having a width of one bit to second words having a width of m bits, wherein m<1.

23. The method of claim 22, wherein quantizing the amplitude information signal comprises:
generating the second words from the m most significant bits of the first words; and
filtering the remaining (1−m) least significant bits using the first filter.

24. The method of claim 19, further comprising quantizing the phase information signal using a second filter of a third order and having fixed filter coefficients, wherein a z transform of a pulse response of the second filter is:
F₂(z)=b₁z⁻¹+b₂z⁻²+b₃z⁻³,
wherein b₁, b₂ and b₃ are each a filter coefficient.

25. The method of claim 19, further comprising quantizing the phase information signal using a second filter of a third order and having fixed filter coefficients, wherein a z transform of a pulse response of the second filter is:
F₁(z)=−z⁻¹+z⁻²+z⁻³.

26. The method of claim 19, wherein quantizing the amplitude information signal comprises quantizing the amplitude information signals from first words having a width of j bits to second words having a width of k bits, wherein k<j.

27. The method of claim 26, wherein quantizing the amplitude information signal comprises:
generating the second words from the k most significant bits of the first words; and
filtering the remaining (j−k) least significant bits using the first filter.

28. A computer-readable medium storing computer-executable instructions for performing a method, the method comprising:
accumulating a phase increment that comprises an overflow to a phase information signal;
mapping the phase information signal to an amplitude information signal;
quantizing the amplitude information signal while feeding back a quantization noise using a first filter of an n^{th} order, so that the feedback of the quantization noise comprises zeros at least two mutually different frequencies in a transfer function of the first filter; and
performing digital/analog conversion of the quantized amplitude information signal to an oscillation signal.
